(19) United States
(12) Patent Application Publication
(10) Pub. No.: US 2016/0312756 A1
(43) Pub. Date: Oct. 27, 2016

(54) ELECTRONICS MODULE FOR AN IGNITION UNIT

(71) Applicant: Robert Bosch GmbH, Stuttgart (DE)

(72) Inventor: Werner Steinberger, Immenstadt (DE)

(21) Appl. No.: 15/033,204

(22) PCT Filed: Oct. 8, 2014
(86) PCT No.: PCT/EP2014/071497

§ 371 Date: Jul. 6, 2016

(30) Foreign Application Priority Data
Nov. 14, 2013 (DE) 10 2013 223 185.7
May 15, 2014 (DE) 10 2014 209 185.3

(51) Int. Cl. F02P 3/02; H01F 38/12; H05K 5/00; F02P 7/04; H05K 5/06; H05K 5/02

(52) U.S. Cl. CPC F02P 3/02; H05K 5/064; H05K 5/0217; H05K 5/0008; H05K 5/0247; F02P 7/04; H01F 38/12

(57) ABSTRACT

An electronics module and an ignition unit having such an electronics module are described, which include: a housing having a receptacle for an electronics assembly and an electrical interface for connection to an ignition coil. The housing includes a mechanical interface for fastening on an ignition coil housing. The mechanical interface further includes a collar, which is configured to be integrally joined to a casting compound to be filled into the ignition coil housing.

### FIELD OF THE INVENTION

The present invention relates to an electronics module for an ignition unit. In particular, the present invention relates to improvements in the connection of an electronics module to an ignition coil unit.

### BACKGROUND INFORMATION

Ignition units are believed to be understood in the related art for igniting combustible fuel mixtures in internal combustion engines at predefined points in time. The ignition voltage is frequently generated with mediation of an ignition coil, which is accommodated in some embodiments in a separate housing or housing part. An electronics module is connected to the ignition coil for monitoring and regulating the ignition procedures, the electronics module also including a separate housing or a separate housing part in some embodiments. The electronics module usually includes an electronic circuit board, on which power electronics are provided, for example, in the form of an ignition IGBT, diagnostic electronics, or a multi-spark activation unit. The electronics module is conventionally screwed onto the ignition coil housing or fixed thereon via an ultrasonic welded joint. Even if a separate embodiment of the housing (or housing parts) means more components and a greater installation outlay for the electronics module and the ignition. coil unit, a better (modular) adaptation of the ignition unit to customer-specific wishes may take place without changes on the basic ignition coil. In addition to a mechanical connection of the two housings, however, additional electrical contacting has to be carried out between the electronics module and ignition coil unit. Thermal decoupling between the ignition coil unit and the electronics module may be implemented more easily in the case of separate housings, however. It is an object of the present invention to make a connection between an electronics module and an ignition coil unit simpler and less complex in the installation.

### SUMMARY OF THE INVENTION

The above-mentioned object may be achieved according to the present invention by an electronics module for an ignition unit and by an ignition unit and a method for filling an ignition unit.

Accordingly, an electronics module for an ignition unit having a housing is provided, in which a receptacle for an electronics assembly is situated. The electronics assembly may be provided, for example, for activating the ignition coil and may include a circuit board or may essentially be configured as a circuit board. The ignition coil is not an integral part of the electronics module according to the present invention. The housing of the electronics module according to the present invention furthermore includes a mechanical interface for fastening on an ignition coil housing, in which the ignition coil is situated.

According to the present invention, the mechanical interface has a collar connected to the housing of the electronics module according to the present invention. The collar is configured to be integrally joined to a casting compound to be filled into the ignition coil housing. An integrally joined connection does not preclude in this case, according to the present invention, a mechanical undercut or other suitable connections additionally being provided or being established, by the casting compound. Such a casting compound is used in particular for the electrical insulation of the ignition coil and results in higher mechanical strength of the assembly.

For example, an epoxy resin (optionally having a filler material) is infused at low pressure into the housing to achieve a particularly complete filling. The housing of the electronics module may furthermore be equipped with a positioning unit, which is configured to position the electrical interface and the mechanical interface in relation to one another with respect to the ignition coil housing in the course of a plug-in procedure and to guide the plug-in procedure. In the course of the plug-in procedure, the electronics module is fastened on an ignition coil unit and connected via electrical contacts to the ignition coil. The electrical contacts may be situated in such a way, in particular inside a circumferential collar, that they are enclosed fluid-tight in the course of the plug-in procedure between the housing of the electronics module and the ignition coil housing. After solidification of the casting compound, the housing of the electronics module according to the present invention and the ignition coil housing are integrally joined via the casting compound, which makes an additional connection (for example, a screw connection) superfluous and supplements the optional connection via the positioning unit. The electronics module according to the present invention enables a cost-effective ignition unit, which is simple to manufacture, and in which the electronics module may be used with a great diversity of variants of the ignition coil unit and therefore different ignition units may be modularly implemented.

The further descriptions herein present further refinements of the present invention.

An electrical interface is advantageously also provided in the housing of the electronics module according to the present invention for connecting the electronics assembly to an ignition coil. It may be provided as part of a plug connection, so that when the housing of the electronics module according to the present invention is brought together with the ignition coil housing, the receptacle for the electronics assembly is automatically electrically connected to the ignition coil or to an electrical interface thereof.

The positioning unit may have a detent element. The positioning unit may implement a form-locked connection between the electronics module and the ignition coil unit in addition to the guiding during the plug-in procedure. The form-locked connection may be configured, for example, as a bayonet connection and additionally or alternatively include a snap/latching connection. In this way, a simple connection is established between the housing of the electronics module and the ignition coil housing, until the casting compound is introduced and solidifies. This simplifies the manufacture and lowers the manufacturing costs.

Furthermore, the collar may be configured to plunge into a cavity of the ignition coil housing, and in particular includes a surface which promotes form-locked undercuts, which may be in the form of multiple passages and/or boreholes. The mechanical interface may implement both relative positioning and an integrally joined and/or form-locked connection of the housing of the electronics module according to the present invention and the ignition coil housing.

According to one refinement, the electronics module according to the present invention includes a filling channel, which has a second opening, which faces toward the mechanical interface, and a first opening opposite to the second opening. A casting compound may pass over from the housing of the electronics module into a cavity inside the ignition coil housing via the filling channel. In this way, the casting compound is guided, for example, past the receptacle for the electronics assembly or past the electronics assembly of the electronics module, and separate filling of the ignition coil housing with the casting compound may be omitted. This also simplifies the manufacturing process of the electronics module according to the present invention.

The second opening of the filling channel may have a structure protruding in the direction of the ignition coil housing, which is configured to plunge into the casting compound to be filled in. If the structure is provided circumferentially, the surface of the casting compound outside the filling channel is hermetically separated from the surface inside the filling channel after the filling, whereby penetration of contaminants and water is prevented.

Furthermore, a wall may be situated between the receptacle for the electronics assembly and the filling channel. The wall may represent a part of the filling channel, for example, and may represent a type of dam or overflow for the casting compound filled into the first housing or into the receptacle. In this way, it is ensured that during filling of the casting compound into the housing or into the receptacle, a suitable fill level of the casting compound is reached before the casting compound may run via the filling channel into the ignition coil housing.

If filling of the volume, which includes the ignition coil, with a first casting compound and of the volume, which includes the receptacle for the electronics assembly, using a second casting compound, which is materially different is desired, no overflow is required. In this case, a type of funnel may be provided on the first opening of the filling channel to make the filling procedure easier.

Furthermore, the filling channel may be oriented essentially in a direction of the plug-in procedure. Thus, for example, if the electronics mconfiguredodule is placed from above onto the ignition coil unit, the filling channel for the casting compound also extends from top to bottom. In this way, the casting compound is distributed within the ignition unit solely as a result of gravity.

Furthermore, the housing of the electronics module according to the present invention may furthermore include a circumferential collar, which encloses an electronics assembly situated in the housing, as does the first opening of the filling channel. In this way, the circumferential collar may be used during filling of the electronics module according to the present invention for keeping the casting compound in position above the electronics assembly.

A wall of the filling channel may be provided in the area of the first opening with a recess extending in the direction of the second opening. In other words, for example, an area of the first opening of the filling channel, configured as the upper edge, is configured to be lowered in relation to the surrounding edge sections, so that a type of overflow or drain is formed for the casting compound poured onto the electronics assembly. In this way, the casting compound automatically drains off into the channel from a fill level determined by the recess and results in filling of the ignition coil unit, whereby a separate filling procedure may be omitted. An overflow of the casting compound is prevented, for example, by the circumferential collar.

Furthermore, the housing of the electronics module according to the present invention may be configured to mechanically fix the ignition unit on a periphery of the ignition unit, for example, an engine block. The housing may have screw-on points for this purpose in particular. In this way, all interfaces which are typically specified by the wishes of the customer, such as electrical and mechanical connections, may be situated in the housing of the electronics module according to the present invention. Therefore, costly insert tools and a handling unit required for them are superfluous during the manufacturing of the ignition coil housing, which reduces the costs for covering a required variant diversity.

Furthermore, a fill level of the casting compound inside the ignition coil housing may be selected in such a way that a cavity remains for the thermal insulation between the ignition coil and the receptacle for the electronics assembly. In other words, the ignition coil housing is not completely filled with casting compound, so that the surface of the casting compound does not directly adjoin an upper boundary of the volume, by which the ignition coil housing adjoins in the direction of the housing of the electronics module according to the present invention. In this way, heating of the ignition coil may heat up the electronics assembly only to a reduced extent. Malfunctions or required power reductions of the electronics assembly may therefore be avoided.

Furthermore, the collar of the mechanical interface may be configured in such a way that, in cooperation with the ignition coil housing or with a corresponding structure situated thereon, it forms a gap or multiple gaps, for example, capillary gaps. For this purpose, the collar of the mechanical interface may be provided, for example, as a fractionally or completely circumferential collar on the lower side of the housing, which is situated directly inside a corresponding collar provided on the ignition coil housing. The capillary effect between these two above-mentioned collars yields a filled-in casting compound that results, over a large area, in an integrally joined connection between the housing and the ignition coil housing. According to a second aspect of the present invention, an ignition unit, including an ignition coil unit having an ignition coil and an ignition coil housing and also an electronics module is provided, the above statements applying accordingly to the electronics module. The ignition coil housing and the housing of the electronics module are nested and electrically contacted with one another via the mechanical interface. According to the present invention, an integrally joined and/or form-locked connection of the housing of the electronics module according to the present invention and the ignition coil housing may be implemented via a casting compound. The feature combinations and the advantages thereof result in accordance with the first mentioned aspect of the present invention.

The ignition unit according to the present invention may be configured in such a way that a filling channel is formed, which is configured to guide fluid overflowing from the first cavity in the housing of the electronics module into a second cavity in the housing of the ignition coil unit. In this way, a single filling procedure may fill two cavities inside the ignition unit according to the present invention with a casting compound, so that separate filling of the two cavities may be omitted. The filling channel of the ignition unit according to the present invention may also be configured in accordance with the statements in conjunction with the first-mentioned aspect of the present invention.

According to a third aspect of the present invention, a method is provided for filling an ignition unit, including an electronics module and an ignition coil unit, with a casting compound. The ignition unit may be configured as stated in conjunction with the second-mentioned aspect of the present invention. The casting compound is initially measured according to the present invention so that a predefined quantity of the casting compound results. The quantity may be determined on the basis of the volumes to be filled of the first cavity and the second cavity. This may be carried out by computer or by a test or a series of tests. To improve the degree of filling and avoid foreign objects and air entrapments, the ignition unit may now be evacuated. The predefined quantity of casting compound is subsequently cast into an upper cavity of the electronics module, so that a part of the quantity of the casting compound runs via an overflow of the upper cavity into a lower cavity of the ignition coil unit. It is not necessary for the ignition unit to have the same orientation during the casting procedure as it assumes during a subsequent curing period for curing the casting compound. In this way, the volume of the casting compound which runs into the lower cavity may be determined independently of a curing position. In other words, the overflow or the first opening of the filling channel is only to be determined in such a way that, during the casting, a volume defined by the overflow of the channel remains inside the upper cavity during the subsequent curing. This enables simple filling of an ignition unit with a casting compound.

To ensure an orderly passage of the casting compound from the upper cavity into the lower cavity, the overflow of the upper cavity opens into a channel which connects a housing of the electronics module and an ignition coil housing of the ignition coil unit to one another. In other words, the channel is configured in such a way that casting compound overflowing from the upper cavity automatically runs into the lower cavity inside the ignition coil housing. A connection via a filling channel enables particularly process-reliable filling of both cavities.

Exemplary embodiments of the present invention are described in detail hereafter with reference to the appended drawings.

### BRIEF DESCRIPTION OF THE DRAWINGS

FIG. 1 shows a perspective view of one first exemplary embodiment of an ignition unit according to the present invention.

FIG. 2 shows a perspective view of one second exemplary embodiment of the ignition unit according to the present invention.

FIG. 3 shows a perspective detail view of one exemplary embodiment of a channel having a drain for a casting compound.

FIG. 4 shows a sectional side view of one exemplary embodiment of an ignition unit according to the present invention, illustrating casting compound fill level.

FIG. 5 shows a flow chart illustrating steps of one exemplary embodiment of a method according to the present invention.

### DETAILED DESCRIPTION

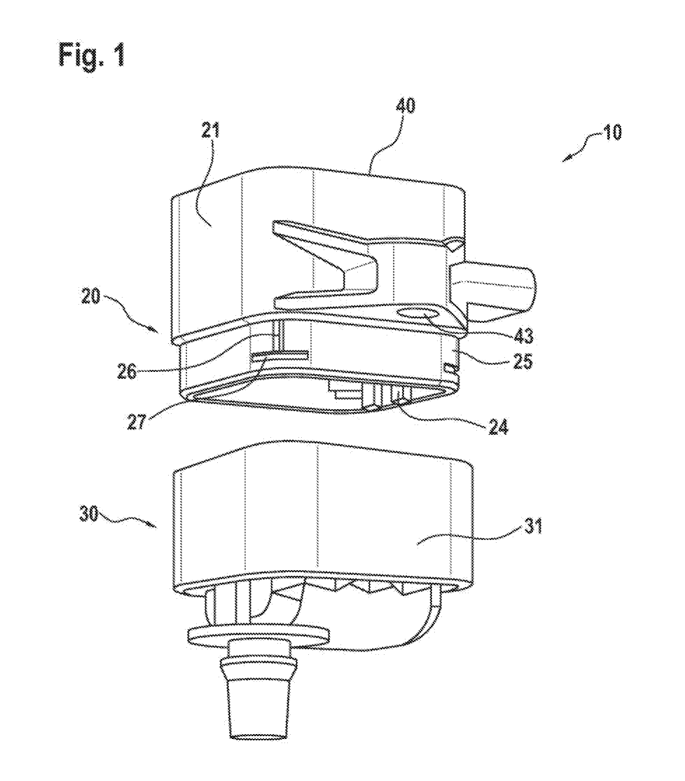

FIG. 1 shows one exemplary embodiment of an ignition unit 10 according to the present invention, ignition coil unit 30 and electronics module 20 of which have not yet been assembled. Housing 21 of electronics module 20 has on its lower edge a collar 25, which extends around an essentially square footprint. The corners of the essentially square footprint are rounded, for example, a rib 26 being situated on each of the rounded corners as a positioning unit. In addition, a detent element of a latching connection may be provided on each of the corners. Two electrical contacts 24 oriented in the direction of ignition coil unit 30 are recognizable inside circumferential collar 25. Electrical contacts 24 are pre-positioned by ribs 26 of collar 25 in such a way that they are inserted securely into the electrical counter contacts of the ignition coil. Electronics module 20 is therefore configured via collar 25 and via ribs 26 and detent elements 27 to permanently contact ignition coil housing 31 of ignition coil unit 30 via a plug-in procedure. Screw-on points 43, which are integrally molded onto housing 21, enable mechanical fixing of ignition unit 10 on a periphery of ignition unit 10.

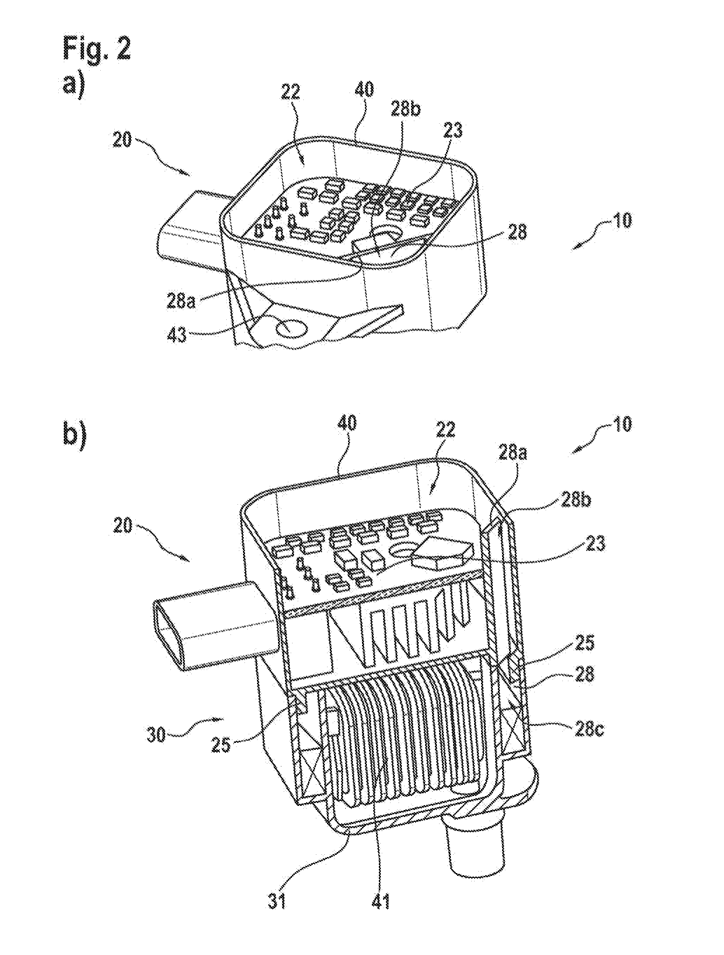

FIG. 2 shows, in an upper partial figure a), a perspective top view of an electronics module according to FIG. 1 having an electronics assembly 23 situated inside a collar 40 and having a filling channel 28 situated in a corner area of collar 40. Filling channel 28 is delimited laterally on one side by collar 40, and on the other side by a wall 28a, which forms a filament. A first (upper) opening 28b of filling channel 28 is situated at this point. Filling channel 28 extends past electronics module 23 in the direction of ignition coil unit 30. Screw-on points 43, which are integrally molded on the housing 21, enable mechanical fixing of ignition unit 10 on a periphery of ignition unit 10.

Electronics module 20 according to the present invention includes a housing 21 having a receptacle 22 for electronics assembly 23. Receptacle 22 is formed by collar 40 and a base. Circumferential collar 40, which is ring-shaped or rectangular, and which forms mechanical interface 25 to ignition coil housing 31, is situated on the lower side of the base, facing away from receptacle 22. Filling channel 28 according to the present invention is situated inside collar 40 of receptacle 22, but is completely or at least sectionally separated from receptacle 22. Filling channel 28 according to the present invention extends through the base into the area enclosed by collar 40. According to the exemplary embodiment, filling channel 28 is provided in a corner of collar 40, a partition wall 28a extending from one side of collar 40 to an adjoining side of collar 40 and, together with collar 40, forming filling channel 28.

Electrical contacts 24 are provided on the electronics module 20, which electrically connect electronics assembly 23 to ignition coil 41 via a plug connection, when electronics module 20 is plugged onto ignition coil housing 31.

A perspective view in partial section of an ignition unit 10 is shown in lower partial figure b), in which electronics module 20 is connected to ignition coil unit 30. Channel 28 is also cut away, so that it is recognizable how it represents a continuous connection to a second (lower) opening 28c between an upper area of electronics module 20 and a space inside housing which contains ignition coil 41.

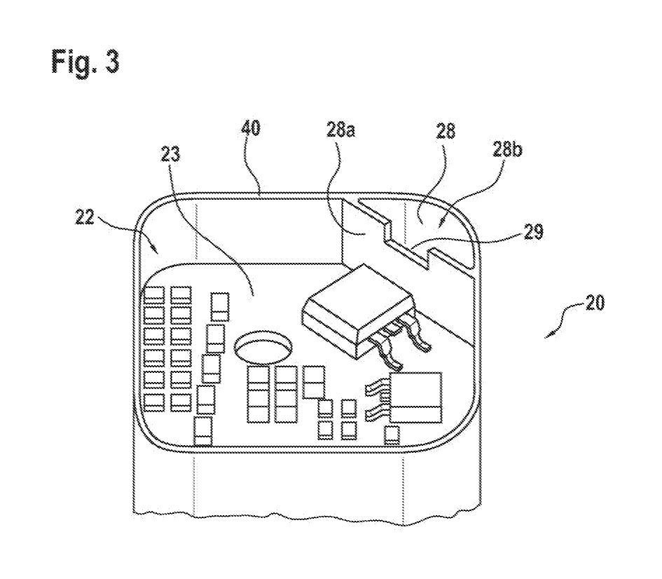

FIG. 3 shows a perspective top view of an electronics module 20, which is open toward the top, first (upper) opening 28b of a channel 28 being recognizable in the detail. The fill level of a casting compound, which is to be filled into collar 40 for casting electronics assembly 23, is determined by recess 29, via which a casting compound (not shown.) may drain through channel 28 in the direction of ignition coil 41 after reaching a predetermined fill level.

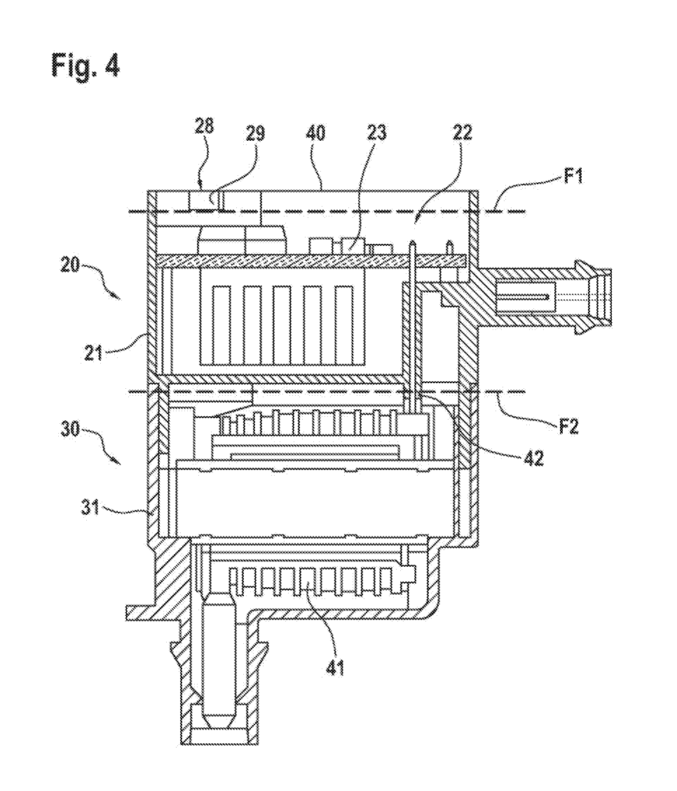

FIG. 4 shows a sectional side view of the exemplary embodiment shown in FIG. 2b), in which fill levels F1, F2 for a casting compound are marked inside collar 40 of electronics module 20 and inside a cavity of ignition coil housing 31 of ignition coil unit 30. Fill level F1 is determined by recess 29, while fill level F2 is determined by the volume inside the ignition coil housing 31 and the volume below recess 29 inside housing 21 in conjunction with a predefined quantity of the casting compound. A collar 40 is situated as a protruding structure on a lower opening 28c of channel 28 in such a way that it is configured to plunge into the casting compound to be filled into the volume inside the ignition coil housing 31 and to hermetically seal the surface thereof outside the channel, whereby penetration of contaminants and water is prevented. Fill level F2 of the casting compound may be selected in such a way that the casting compound and mechanical interface 25 are integrally joined.

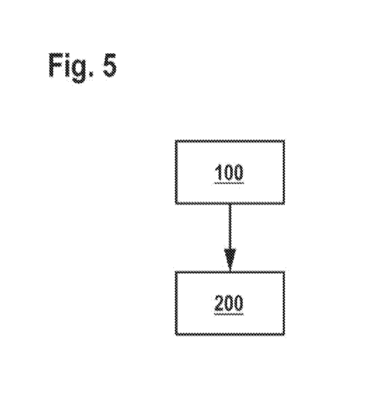

FIG. 5 shows a flow chart, illustrating steps of one exemplary embodiment of a method according to the present invention. In step 100, a quantity of a casting compound which is to be filled into the ignition unit according to the present invention is predefined. On the basis of desired fill levels F1, F2 and on the basis of the volumes to be filled and the position of recess 29, the result to be achieved may be decisively influenced via the quantity of the casting compound. Subsequently, in step 200, the predefined quantity of the casting compound is cast into an upper cavity of electronics module 20, so that a part of the quantity of the casting compound runs via an overflow of the upper cavity into a lower cavity of the ignition coil unit. It is apparent to those skilled in the art that the position of ignition unit 10 according to the present invention during the filling of ignition unit 10 with the casting compound (not shown) does not have to be the same as the position in which the casting compound cures.

Although the aspects according to the present invention and advantageous specific embodiments have been described in detail on the basis of the exemplary embodiments explained in conjunction with the appended figures of the drawing, modifications and combinations of features of the illustrated exemplary embodiments are possible for those skilled in the art, without departing from the framework of the present invention, the scope of protection of which is defined by the claims.

1-16. (canceled)

17. An electronics module for an ignition unit, comprising:
a housing having a receptacle for an electronics assembly, the housing including a mechanical interface for fastening on an ignition coil housing;
wherein the mechanical interface includes a collar, which is connected to the housing, and which is integrally joinable to a casting compound to be filled into the ignition coil housing.

18. The electronics module of claim 17, wherein the collar is plunge-able into a cavity of the ignition coil housing.

19. The electronics module of claim 17, wherein the receptacle includes a base, the collar being situated on the side of the base facing away from the receptacle.

20. The electronics module of claim 17, further comprising:
a filling channel, wherein the filling channel includes a first opening on a first side of the receptacle, and includes a second opening on a second side of the receptacle.

21. The electronics module of claim 19, wherein the second opening of the filling channel includes a structure, which protrudes in a direction of the ignition coil housing, and which is plunge-able into the casting compound to be filled in.

22. The electronics module of claim 19, wherein a wall is situated between the receptacle and the filling channel.

23. The electronics module of claim 21, wherein the wall is provided, in the area of the first opening of the filling channel, with a recess extending in the direction of the second opening.

24. The electronics module of claim 17, wherein the housing includes a circumferential collar, which is opposite to the mechanical interface, and which is configured to enclose an electronics assembly situated in the housing and the first opening of the filling channel.

25. The electronics module of claim 17, wherein the housing is configured to mechanically fix the ignition unit on a periphery of the ignition unit, for which the housing includes screw-on points.

26. The electronics module of claim 17, wherein the collar forms, in cooperation with the ignition coil housing, at least one gap for the casting compound.

27. The electronics module of claim 17, further comprising:
an electrical interface to connect the electronics assembly to an ignition coil in the ignition coil housing, the electrical interface being a part of a plug connection.

28. An ignition unit, comprising:
an ignition coil unit having an ignition coil and an ignition coil housing; and
an electronics module, including a housing having a receptacle for an electronics assembly, the housing having a mechanical interface for fastening on an ignition coil housing, wherein the mechanical interface includes a collar, which is connected to the housing, and which is integrally joinable to a casting compound to be filled into the ignition coil housing;
wherein the ignition coil housing and the housing of the electronics module are nested via the mechanical interface and are integrally joinable by the casting compound.

29. The ignition unit of claim 28, further comprising:
a filling channel to guide fluid overflowing from a first cavity in the housing of the electronics module into a second cavity in the ignition coil housing.

30. The ignition unit of claim 28, wherein a fill level of the casting compound is selected so that a cavity remains for thermal insulation between the ignition coil and a receptacle for an electronics assembly provided in the housing.

31. A method for filling an ignition unit with a casting compound, the method comprising:
predefining a quantity of a casting compound; and
casting the predefined quantity of the casting compound into an upper cavity of an electronics module of the ignition unit, so that a part of the quantity of the casting compound runs via an overflow of the upper cavity into a lower cavity of an ignition coil unit of the ignition unit;
wherein the ignition unit includes:
the ignition coil unit, which has an ignition coil and an ignition coil housing; and
the electronics module, which includes a housing having a receptacle for an electronics assembly, the housing having a mechanical interface for fastening on an ignition coil housing, wherein the mechanical interface includes a collar, which is connected to the housing, and which is integrally joinable to the casting compound to be filled into the ignition coil housing;
wherein the ignition coil housing and the housing of the electronics module are nested via the mechanical interface and are integrally joinable by the casting compound.

32. The method of claim 14, wherein the overflow of the upper cavity opens into a filling channel, which connects a housing of the electronics module and an ignition coil housing of the ignition coil unit to one another.

33. The electronics module of claim 17, wherein the collar is plunge-able into a cavity of the ignition coil housing, and includes a surface which promotes form-locked undercuts.

34. The electronics module of claim 17, wherein the collar is plunge-able into a cavity of the ignition coil housing, and includes a surface which promotes form-locked undercuts, in the form of at least one of passages and boreholes.

35. The electronics module of claim 17, further comprising:
a filling channel, wherein the filling channel includes a first opening on a first side of the receptacle, and includes a second opening on a second side of the receptacle, wherein the first side is opposite to the second side.
